(19) United States
(12) Patent Application Publication
(10) Pub. No.: US 2026/0107736 A1
(43) Pub. Date: Apr. 16, 2026

(54) INTERFACE MODULE, METHOD OF OPERATING THE SAME, AND SUBSTRATE PROCESSING APPARATUS

(71) Applicant: SEMES CO., LTD., Cheonan-si (KR)

(72) Inventors: Ki Won HAN, Cheonan-si (KR); Doo Hyun BAEK, Cheonan-si (KR); Hee Chan KIM, Cheonan-si (KR); Sang Oh KIM, Cheonan-si (KR)

(73) Assignee: SEMES CO., LTD., Cheonan-si (KR)

(21) Appl. No.: 19/269,597

(22) Filed: Jul. 15, 2025

(30) Foreign Application Priority Data
Oct. 14, 2024 (KR) 10-2024-0139450

(51) Int. Cl. H01L 21/677; H01L 21/67; H01L 21/687

(52) U.S. Cl. CPC H10P 72/3302; H10P 72/0464; H10P 72/7602

(57) ABSTRACT

Disclosed are an interface module capable of increasing substrate throughput, a method of operating the interface module, and a substrate processing apparatus including the interface module. The interface module configured to load and unload a substrate in the substrate processing apparatus includes a load port module including a plurality of load ports configured to allow a container accommodating a substrate to be placed thereon and an index module disposed on one side of the load port module and configured to unload the substrate from the container and load the substrate into a buffer module or to load a substrate processed in the substrate processing apparatus into the container.

### CROSS-REFERENCE TO THE RELATED APPLICATION

The present application claims priority to and the benefit of Korean Patent Application No. 10-2024-0139450, filed on Oct. 14, 2024, in the Korean Intellectual Property Office, the entire disclosure of which is incorporated herein by reference.

### BACKGROUND

### 1. Field

The present disclosure relates to an interface module, a method of operating the interface module, and a substrate processing apparatus including the interface module.

### 2. Description of the Related Art

A semiconductor (or display) manufacturing process is a process for manufacturing a semiconductor device on a substrate (e.g., a wafer), and includes, for example, exposure, deposition, etching, ion implantation, and cleaning. In order to perform respective manufacturing processes, substrate processing apparatuses that perform respective processes are provided in a cleanroom of a semiconductor manufacturing plant, and processing is performed on substrates loaded in the substrate processing apparatuses.

After being loaded in an interface module of a substrate processing apparatus, a substrate is supplied to individual processing modules by a transfer module. A processed substrate is accommodated in a dedicated container and discharged through the transfer module and the interface module. The interface module broadly includes a load port module on which a container accommodating a substrate is placed and an index module that unloads a substrate from the load port module and provides the substrate to the transfer module or that receives a substrate from the transfer module and loads the substrate into the container. For more efficient transfer, a buffer module for temporarily storing the substrate may be provided between the interface module and the transfer module.

In order to enhance the throughput of a substrate processing apparatus, various approaches have been proposed to more rapidly transfer a substrate from a load port module to a buffer module. As a simple approach, increasing the speed of an index robot in an interface module has been suggested. However, such an approach has a limitation on the extent to which the speed is increased.

### SUMMARY

The present disclosure provides an interface module capable of increasing substrate throughput, a method of operating the interface module, and a substrate processing apparatus including the interface module.

An interface module configured to load and unload a substrate in a substrate processing apparatus according to the present disclosure includes a load port module including a plurality of load ports configured to allow a container accommodating a substrate to be placed thereon and an index module disposed on one side of the load port module and configured to unload the substrate from the container and load the substrate into a buffer module or to load a substrate processed in the substrate processing apparatus into the container. The index module includes an index chamber, vertical gantry members located at both sides of the index chamber, a horizontal gantry member coupled to the vertical gantry members so as to be movable in a vertical direction and extending in a first horizontal direction perpendicular to the vertical direction, and an index robot set including a plurality of index robots configured to be movable along the horizontal gantry member. The buffer module includes an upper buffer and a lower buffer disposed in the vertical direction.

According to an embodiment of the present disclosure, the vertical gantry members may be mounted on a wall of the index chamber to which the buffer module is coupled.

According to an embodiment of the present disclosure, the index robot set may include a first index robot configured to move within a first horizontal section of the horizontal gantry member and a second index robot configured to move within a second horizontal section of the horizontal gantry member, excluding the first horizontal section.

According to an embodiment of the present disclosure, the first index robot may be configured to transfer a substrate with respect to a first container placed on a first load port located at one side of the load port module, and the second index robot may be configured to transfer a substrate with respect to a second container placed on a second load port of the load port module.

According to an embodiment of the present disclosure, the first index robot and the second index robot may be configured to access the buffer module at different times in sequence.

According to an embodiment of the present disclosure, the index robot set may be configured to transfer a substrate unloaded from the container to the lower buffer and to load a substrate received in the upper buffer into the container.

According to an embodiment of the present disclosure, the index robot set may be configured to transfer a substrate unloaded from the container to the upper buffer and to load a substrate received in the lower buffer into the container.

According to an embodiment of the present disclosure, the index robot set may be configured to transfer a substrate unloaded from the container to a first sub-region of the upper buffer and to load a substrate received in a second sub-region of the upper buffer into the container. The first sub-region and the second sub-region may be regions divided in the upper buffer in the vertical direction.

According to an embodiment of the present disclosure, the index robot set may be configured to transfer a substrate unloaded from the container to a first sub-region of the lower buffer and to load a substrate received in a second sub-region of the lower buffer into the container. The first sub-region and the second sub-region may be regions divided in the lower buffer in the vertical direction.

A method of operating the interface module according to the present disclosure includes a substrate unloading step of picking up, by the first index robot, a first substrate from the first container and picking up, by the second index robot, a second substrate from the second container, a substrate transfer step of transferring, by the first index robot, the first substrate to the buffer module and transferring, by the second index robot, the second substrate to the buffer module, a substrate retrieval step of picking up, by the first index robot, the first substrate processed in the substrate processing apparatus from the buffer module and picking up, by the second index robot, the second substrate processed in the substrate processing apparatus from the buffer module, and a substrate loading step of loading, by the first index robot, the first substrate into the first container and loading, by the second index robot, the second substrate into the second container.

According to an embodiment of the present disclosure, in the substrate unloading step and the substrate loading step, the first index robot and the second index robot may operate independently of each other.

According to an embodiment of the present disclosure, in the substrate transfer step and the substrate retrieval step, the first index robot and the second index robot may access the buffer module at different times in sequence.

According to an embodiment of the present disclosure, the first index robot and the second index robot may transfer the first substrate and the second substrate unloaded from the first container and the second container to the lower buffer, and may load the first substrate and the second substrate received in the upper buffer into the first container and the second container.

According to an embodiment of the present disclosure, the first index robot and the second index robot may transfer the first substrate and the second substrate unloaded from the first container and the second container to the upper buffer, and may load the first substrate and the second substrate received in the lower buffer into the first container and the second container.

According to an embodiment of the present disclosure, the first index robot and the second index robot may transfer the first substrate and the second substrate unloaded from the first container and the second container to a first sub-region of the upper buffer, and may load the first substrate and the second substrate received in a second sub-region of the upper buffer into the first container and the second container.

According to an embodiment of the present disclosure, the first index robot and the second index robot may transfer the first substrate and the second substrate unloaded from the first container and the second container to a first sub-region of the lower buffer, and may load the first substrate and the second substrate received in a second sub-region of the lower buffer into the first container and the second container.

A substrate processing apparatus according to the present disclosure includes an interface module configured to load and unload a substrate, a buffer module configured to store the substrate, a main transfer module configured to transfer the substrate to one or more process chambers configured to perform processing on the substrate, and a processing module having the one or more process chambers arranged therein.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows a schematic structure of a substrate processing apparatus according to the present disclosure;

FIG. 2 shows the structure of an interface module according to the present disclosure;

FIG. 3 shows a transfer flow of a substrate in the interface module according to the present disclosure;

FIG. 4 shows a structure in which a substrate is loaded through a lower buffer and is discharged through an upper buffer;

FIG. 5 shows a structure in which each of the lower buffer and the upper buffer includes sub-regions; and

FIG. 6 shows a method of operating the interface module according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

A substrate processing apparatus 1 of an embodiment may be used to perform a process on a substrate W, such as a semiconductor wafer or a flat display panel. In particular, the substrate processing apparatus 1 of the present disclosure may be an apparatus that performs liquid treatment, such as a cleaning process, a coating process, or a developing process, on the substrate W.

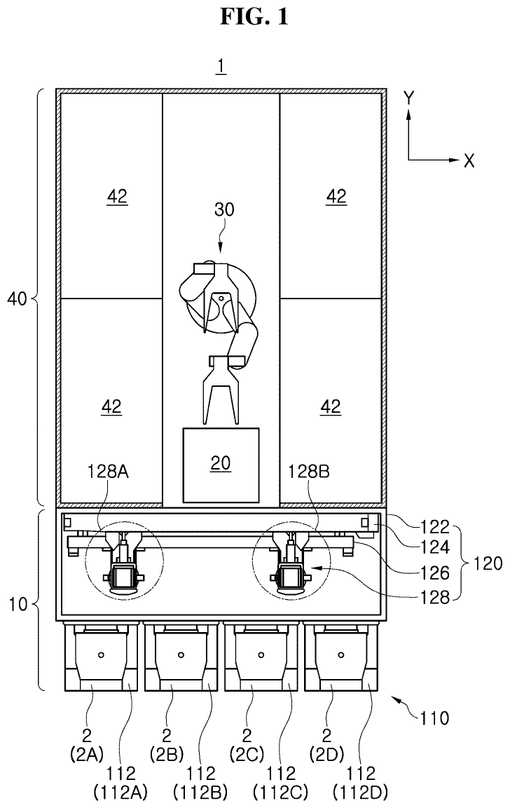

FIG. 1 shows a schematic structure of the substrate processing apparatus 1 according to the present disclosure. The substrate processing apparatus 1 is configured to perform processing on a substrate W loaded therein and to unload a processed substrate W. The substrate processing apparatus 1 includes an interface module 10, a buffer module 20, a transfer module 30, and a processing module 40. In the substrate processing apparatus 1, the interface module 10 may have a shape elongated in a first horizontal direction X. In this specification, the first horizontal direction X is a direction in which the interface module 10 extends. A second horizontal direction Y is a direction perpendicular to the first horizontal direction X. The substrate processing apparatus 1 may have a longitudinal axis that substantially extends in the second horizontal direction Y. A vertical direction Z is a direction perpendicular to both the first horizontal direction X and the second horizontal direction Y.

The interface module 10 is a device that loads and unloads a substrate W in the substrate processing apparatus 1. The interface module 10 includes a load port module 110, which includes a plurality of load ports 112 on which containers 2 accommodating substrates W are placed, and an index module 120, which is disposed on one side of the load port module 110 and is configured to unload the substrate W from the container 2 and load the substrate W into the buffer module 20 or to load the substrate W processed in the substrate processing apparatus 1 into the container 2.

The load port module 110 is disposed at one side of the substrate processing apparatus 1 and is exposed to be accessible from the outside. As shown in FIG. 1, in the substrate processing apparatus 1, the load port module 110 includes a load port 112 on which the container 2 accommodating the substrate W is placed. The load port 112 may be provided in plural, and the plurality of load ports 112 may be disposed in the first horizontal direction X. For example, four load ports 112 may be disposed in the first horizontal direction X. In this case, two load ports 112A and 112B on the left side may be referred to as first load ports, and two load ports 112C and 112D on the right side may be referred to as second load ports.

The container 2 may accommodate the substrate W. A plurality of substrates may be loaded in each container 2. The container 2 may be a front opening unified pod (FOUP) having an openable side. When the container 2 is placed on the load port 112, a door of the load port 112 may be opened by an opener (not shown) of the load port module 110, so that the substrate W may be unloaded. In addition, a processed substrate may be loaded in the container 2. Containers 2A and 2B placed on the first load ports 112A and 112B may be referred to as first containers, and containers 2C and 2D placed on the second load ports 112C and 112D may be referred to as second containers.

The index module 120 is disposed between the load port module 110 and the buffer module 20 in the substrate processing apparatus 1. The index module 120 may unload the substrate W from the container 2 located at the load port module 110 and may transfer the substrate W to the buffer module 20. In addition, the index module 120 may pick up the substrate from the buffer module 20 and may load the substrate W into the container 2.

The index module 120 includes an index chamber 122, vertical gantry members 124 located at both sides of the index chamber 122, a horizontal gantry member 126 extending in the first horizontal direction X, perpendicular to the vertical direction Z, and coupled to the vertical gantry members 124 so as to be movable in the vertical direction Z, and an index robot set 128 including a plurality of index robots 128A and 128B configured to be movable along the horizontal gantry member 126. The detailed structure and operation of the index module 120 will be described later.

The buffer module 20 is disposed between the interface module 10 and the transfer module 30. The buffer module 20 includes a plurality of slots capable of receiving the substrate W. In the buffer module 20, the plurality of slots may be stacked in the vertical direction Z. The buffer module 20 may be open toward the interface module 10 and the transfer module 30. The index robots 128A and 128B and the transfer module 30 may access the buffer module 20 through the open space of the buffer module 20.

The transfer module 30 may pick up the substrate W from the buffer module 20 and may transfer the substrate W to a process chamber 42 that performs processing on the substrate W. In addition, the transfer module 30 may pick up the substrate W processed in the process chamber 42 and may deliver the processed substrate W to the buffer module 20.

Process chambers 42 may be located on both sides of the transfer module 30. In the processing module 40, one or more process chambers 42 are arranged in an array. The processing module 40 may include process chambers 42 arranged in the second horizontal direction Y. In addition, the process chambers 42 may be stacked in two or more levels in the vertical direction Z. FIG. 1 shows an example in which four process chambers 42 are disposed. When the substrate W is loaded in each process chamber 42, processing is performed. The processed substrate may be unloaded from the process chamber 42 by the transfer module 30.

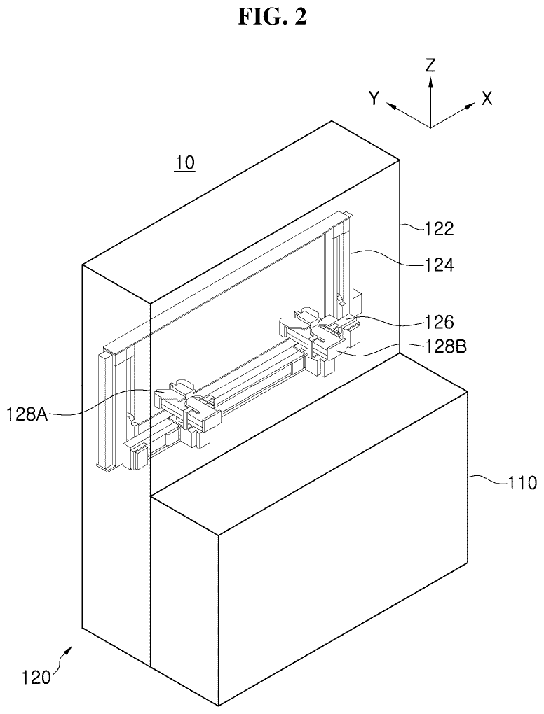

FIG. 2 shows the structure of the interface module 10 according to the present disclosure. Referring to FIG. 2, the load port module 110, on which the container 2 is placed, is exposed to the outside, and the index module 120 is coupled to the load port module 110. The index chamber 122 of the index module 120 has a space defined therein, and the vertical gantry members 124, the horizontal gantry member 126, and the index robot set 128 are mounted in the space in the index chamber 122.

A pair of vertical gantry members 124 is mounted at both sides of the index chamber 122. The vertical gantry members 124 are structures extending in the vertical direction Z. The vertical gantry members 124 provide a path along which the horizontal gantry member 126 may move in the vertical direction Z.

The horizontal gantry member 126 may be coupled to the pair of vertical gantry members 124 and may move in the vertical direction Z. The horizontal gantry member 126 extends in the first horizontal direction X. The horizontal gantry member 126 provides a path along which the index robot set 128 may move in the first horizontal direction X.

The index robot set 128 includes two index robots 128A and 128B. Each of the index robots 128A and 128B may move in the first horizontal direction X along the horizontal gantry member 126 and may move in the vertical direction Z due to the vertical gantry members 124. Each of the index robots 128A and 128B may include a robot arm and a robot hand. Each of the index robots 128A and 128B may move or rotate in the second horizontal direction Y, which is a forward-backward direction.

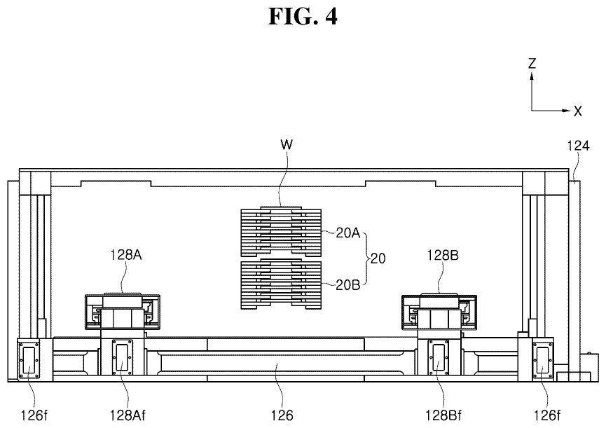

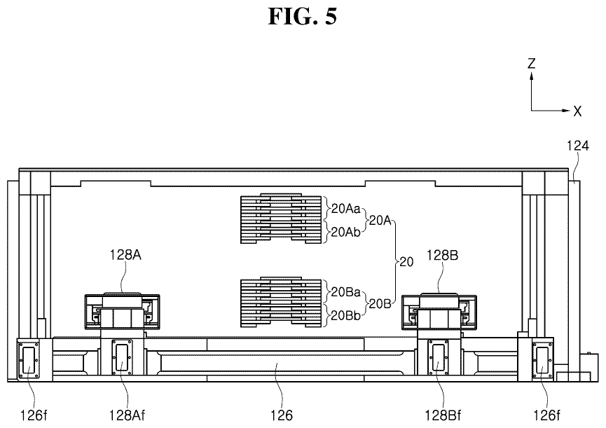

Meanwhile, referring to FIGS. 4 and 5, exhaust fans 126f may be located at both ends of the horizontal gantry member 126. The exhaust fans 126f may discharge air in the forward direction (−Y direction). In addition, exhaust fans 128Af and 128Bf may be disposed below the index robots 128A and 128B, respectively, to discharge air in the forward direction (−Y direction). The exhaust fans may discharge particles together with the air. The air and the particles may be discharged to the outside through an opening formed in a front wall 122B of the index chamber 122.

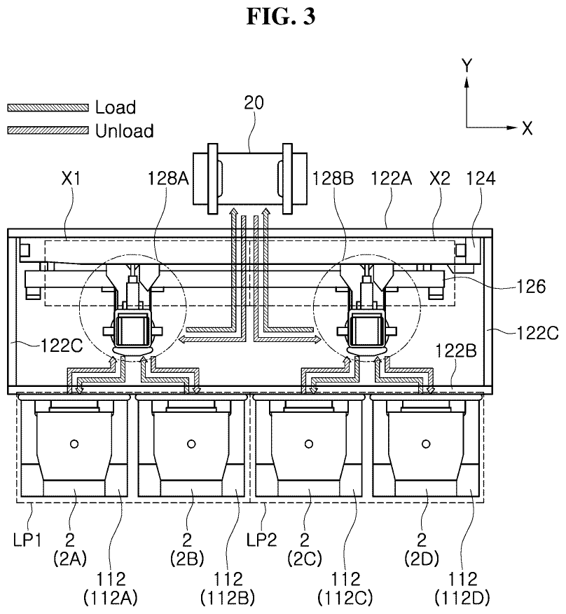

FIG. 3 shows a transfer flow of the substrate in the interface module 10 according to the present disclosure. Referring to FIG. 3, the index chamber 122 includes four walls 122A, 122B, 122C, and 122D that surround the vertical gantry members 124, the horizontal gantry member 126, and the index robot set 128. An opening may be formed in the front wall 122B of the index chamber 122 to allow access to the container 2 located in the load port module 110. An opening may also be formed in the rear wall 122A of the index chamber 122 to allow access to the buffer module 20. The vertical gantry members 124 are mounted on the wall 122A of the index chamber 122 to which the buffer module 20 is coupled.

The index robot set 128 includes a first index robot 128A configured to move within a first horizontal section X1 of the horizontal gantry member 126 and a second index robot 128B configured to move within a second horizontal section X2 of the horizontal gantry member 126, excluding the first horizontal section X1. The horizontal gantry member 126 includes two horizontal sections X1 and X2, which are virtually divided. The first horizontal section X1 is a section within which the first index robot 128A is movable, and the second horizontal section X2 is a section within which the second index robot 128B is movable. However, when one of the index robots is removed or is not operable, the other index robot may travel across the entire section.

The first index robot 128A may transfer the substrate W with respect to the first containers 2A and 2B placed on the first load ports 112A and 112B located at one side of the load port module 110, and the second index robot 128B may transfer the substrate W with respect to the second containers 2C and 2D placed on the second load ports 112C and 112D of the load port module 110. The first index robot 128A may access the first containers 2A and 2B placed on the first load ports 112A and 112B located in a load port region LP1 defined within the first horizontal section X1, and the second index robot 128B may access the second containers 2C and 2D placed on the second load ports 112C and 112D located in a load port region LP2 defined within the second horizontal section X2. As such, since the first index robot 128A and the second index robot 128B transfer the substrates W in separate regions, the transfer throughput of the substrates W may be increased without collision between the robots.

The first index robot 128A and the second index robot 128B are configured to access the buffer module 20 at different times in sequence. In order to prevent collision between the first index robot 128A and the second index robot 128B at the buffer module 20, the timing at which the first index robot 128A accesses the buffer module 20 and the timing at which the second index robot 128B accesses the buffer module 20 may be set differently. For example, the access order of the first index robot 128A and the second index robot 128B to the buffer module 20 may be set to be different. In another example, the first index robot 128A and the second index robot 128B may individually access the buffer module 20, with one of the index robots being granted priority.

The buffer module 20 may include a plurality of buffers disposed in the vertical direction Z. The buffer module 20 may include an upper buffer 20A and a lower buffer 20B. The upper buffer 20A and the lower buffer 20B may be spaced apart from each other. Alternatively, the upper buffer 20A and the lower buffer 20B may be in contact with each other. The upper buffer 20A and the lower buffer 20B may be spaces partitioned within a single structure.

FIG. 4 shows a structure in which the substrate W is loaded through the lower buffer 20B and is discharged through the upper buffer 20A. The index robot set 128 may be configured to transfer the substrate W unloaded from the container 2 to the lower buffer 20B and to load the substrate W received in the upper buffer 20A into the container 2. The first index robot 128A may unload two substrates W from the first containers 2A and 2B, and the second index robot 128B may unload two substrates W from the second containers 2C and 2D. Subsequently, the first index robot 128A may load the substrates W into the lower buffer 20B, and the second index robot 128B may also load the substrates W into the lower buffer 20B. Subsequently, the first index robot 128A may pick up the substrates W from the upper buffer 20A, and the second index robot 128B may also pick up the substrates W from the upper buffer 20A. Subsequently, the first index robot 128A may load the substrates W into the first containers 2A and 2B, and the second index robot 128B may load the substrates W into the second containers 2C and 2D.

Conversely, the substrate W may be loaded through the upper buffer 20A and may be discharged through the lower buffer 20B. The index robot set 128 may be configured to transfer the substrate W unloaded from the container 2 to the upper buffer 20A and to load the substrate W received in the lower buffer 20B into the container 2.

FIG. 5 shows a structure in which each of the lower buffer 20B and the upper buffer 20A includes sub-regions. Referring to FIG. 5, the upper buffer 20A includes a first sub-region 20Aa and a second sub-region 20Ab, which are divided in the vertical direction Z. The lower buffer 20B includes a first sub-region 20Ba and a second sub-region 20Bb, which are divided in the vertical direction Z.

The first sub-region 20Aa of the upper buffer 20A and the first sub-region 20Ba of the lower buffer 20B may serve as spaces in which the substrates W that have already been processed in the processing module 40 are received, and the second sub-region 20Ab of the upper buffer 20A and the second sub-region 20Bb of the lower buffer 20B may serve as spaces in which the substrates W to be supplied to the processing module 40 are received. Conversely, the first sub-region 20Aa of the upper buffer 20A and the first sub-region 20Ba of the lower buffer 20B may serve as spaces in which the substrates W to be supplied to the processing module 40 are received, and the second sub-region 20Ab of the upper buffer 20A and the second sub-region 20Bb of the lower buffer 20B may serve as spaces in which the substrates W that have already been processed in the processing module 40 are received.

The upper buffer 20A and the lower buffer 20B may be buffers that are accessible by both the first index robot 128A and the second index robot 128B. The index robot set 128 may be configured to transfer the substrate W unloaded from the container 2 to the first sub-region 20Aa of the upper buffer 20A and to load the substrate W received in the second sub-region 20Ab of the upper buffer 20A into the container 2. In addition, the index robot set 128 may be configured to transfer the substrate W unloaded from the container 2 to the first sub-region 20Ba of the lower buffer 20B and to load the substrate W received in the second sub-region 20Bb of the lower buffer 20B into the container 2.

In another example, the index robot set 128 may be configured to transfer the substrate W unloaded from the container 2 to the second sub-region 20Ab of the upper buffer 20A and to load the substrate W received in the first sub-region 20Aa of the upper buffer 20A into the container 2. In addition, the index robot set 128 may be configured to transfer the substrate W unloaded from the container 2 to the second sub-region 20Bb of the lower buffer 20B and to load the substrate W received in the first sub-region 20Ba of the lower buffer 20B into the container 2.

The upper buffer 20A may be a buffer that is accessed by the first index robot 128A, and the lower buffer 20B may be a buffer that is accessed by the second index robot 128B. Conversely, the upper buffer 20A may be a buffer that is accessed by the second index robot 128B, and the lower buffer 20B may be a buffer that is accessed by the first index robot 128A.

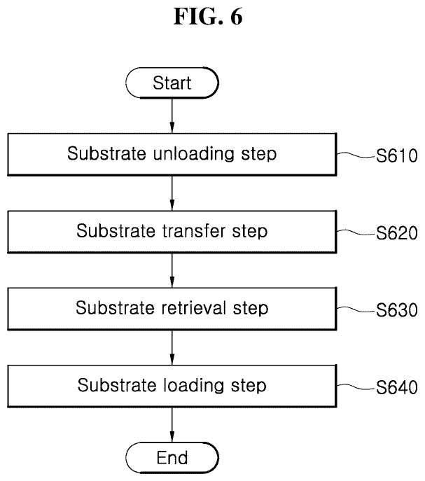

FIG. 6 shows a method of operating the interface module 10 according to the present disclosure. The method of operating the interface module 10 according to the present disclosure includes a substrate unloading step (S610), a substrate transfer step (S620), a substrate retrieval step (S630), and a substrate loading step (S640).

In the substrate unloading step (S610), the first index robot 128A picks up first substrates from the first containers 2A and 2B, and the second index robot 128B picks up second substrates from the second containers 2C and 2D. The first index robot 128A may access the first containers 2A and 2B, which are placed on the first load ports 112A and 112B located in the load port region LP1 defined within the first horizontal section X1. The second index robot 128B may access the second containers 2C and 2D, which are placed on the second load ports 112C and 112D located in the load port region LP2 defined within the second horizontal section X2. In the substrate unloading step S610, the first index robot 128A and the second index robot 128B may operate independently of each other.

In the substrate transfer step (S620), the first index robot 128A transfers the first substrates to the buffer module 20, and the second index robot 128B transfers the second substrates to the buffer module 20. In the substrate transfer step S620, the first index robot 128A and the second index robot 128B may access the buffer module 20 at different times in sequence. The first index robot 128A may first access the buffer module 20, and then the second index robot 128B may access the buffer module 20. Alternatively, the second index robot 128B may first access the buffer module 20, and then the first index robot 128A may access the buffer module 20.

In the substrate retrieval step (S630), the first index robot 128A picks up the first substrates processed in the substrate processing apparatus 1 from the buffer module 20, and the second index robot 128B picks up the second substrates processed in the substrate processing apparatus 1 from the buffer module 20. In the substrate retrieval step (S630), the first index robot 128A and the second index robot 128B may access the buffer module 20 at different times in sequence. The first index robot 128A may first access the buffer module 20, and then the second index robot 128B may access the buffer module 20. Alternatively, the second index robot 128B may first access the buffer module 20, and then the first index robot 128A may access the buffer module 20.

In the substrate loading step (S640), the first index robot 128A loads the first substrates into the first containers 2A and 2B, and the second index robot 128B loads the second substrates into the second containers 2C and 2D. In the substrate loading step S640, the first index robot 128A and the second index robot 128B may operate independently of each other.

When the buffer module 20 is configured as shown in FIG. 4, in the substrate transfer step (S620), the first index robot 128A and the second index robot 128B may transfer the first substrates and the second substrates unloaded from the first containers 2A and 2B and the second containers 2C and 2D to the lower buffer 20B. In the substrate retrieval step (S630), the first index robot 128A and the second index robot 128B may load the first substrates and the second substrates received in the upper buffer 20A into the first containers 2A and 2B and the second containers 2C and 2D.

Conversely, in the substrate transfer step (S620), the first index robot 128A and the second index robot 128B may transfer the first substrates and the second substrates unloaded from the first containers 2A and 2B and the second containers 2C and 2D to the upper buffer 20A, and may then load the first substrates and the second substrates received in the lower buffer 20B into the first containers 2A and 2B and the second containers 2C and 2D.

When the buffer module 20 is configured as shown in FIG. 5, in the substrate transfer step (S620), the first index robot 128A and the second index robot 128B may transfer the first substrates and the second substrates unloaded from the first containers 2A and 2B and the second containers 2C and 2D to the first sub-region 20Aa of the upper buffer 20A. In the substrate retrieval step (S630), the first index robot 128A and the second index robot 128B may load the first substrates and the second substrates received in the second sub-region 20Ab of the upper buffer 20A into the first containers 2A and 2B and the second containers 2C and 2D.

In addition, in the substrate transfer step (S620), the first index robot 128A and the second index robot 128B may transfer the first substrates and the second substrates unloaded from the first containers 2A and 2B and the second containers 2C and 2D to the first sub-region 20Ba of the lower buffer 20B. In the substrate retrieval step (S630), the first index robot 128A and the second index robot 128B may load the first substrates and the second substrates received in the second sub-region 20Bb of the lower buffer 20B into the first containers 2A and 2B and the second containers 2C and 2D.

Conversely, in the substrate transfer step (S620), the first index robot 128A and the second index robot 128B may transfer the first substrates and the second substrates unloaded from the first containers 2A and 2B and the second containers 2C and 2D to the second sub-region 20Ab of the upper buffer 20A. In the substrate retrieval step (S630), the first index robot 128A and the second index robot 128B may load the first substrates and the second substrates received in the first sub-region 20Aa of the upper buffer 20A into the first containers 2A and 2B and the second containers 2C and 2D.

In addition, in the substrate transfer step (S620), the first index robot 128A and the second index robot 128B may transfer the first substrates and the second substrates unloaded from the first containers 2A and 2B and the second containers 2C and 2D to the second sub-region 20Bb of the lower buffer 20B. In the substrate retrieval step (S630), the first index robot 128A and the second index robot 128B may load the first substrates and the second substrates received in the first sub-region 20Ba of the lower buffer 20B into the first containers 2A and 2B and the second containers 2C and 2D.

As is apparent from the above description, according to the present disclosure, because a plurality of index robots is provided in the index module and the buffer module includes an upper buffer and a lower buffer separated from each other, an efficient substrate transfer path may be formed, which may result in improved substrate throughput.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. An interface module configured to load and unload a substrate in a substrate processing apparatus, the interface module comprising:
a load port module comprising a plurality of load ports configured to allow a container accommodating a substrate to be placed thereon; and
an index module disposed on one side of the load port module, the index module being configured to unload the substrate from the container and load the substrate into a buffer module or to load a substrate processed in the substrate processing apparatus into the container,
wherein the index module comprises:
an index chamber;
vertical gantry members located at both sides of the index chamber;
a horizontal gantry member coupled to the vertical gantry members so as to be movable in a vertical direction, the horizontal gantry member extending in a first horizontal direction perpendicular to the vertical direction; and
an index robot set comprising a plurality of index robots configured to be movable along the horizontal gantry member, and
wherein the buffer module comprises an upper buffer and a lower buffer disposed in the vertical direction.

2. The interface module as claimed in claim 1, wherein the vertical gantry members are mounted on a wall of the index chamber, the buffer module being coupled to the wall.

3. The interface module as claimed in claim 1, wherein the index robot set comprises:
a first index robot configured to move within a first horizontal section of the horizontal gantry member; and
a second index robot configured to move within a second horizontal section of the horizontal gantry member, excluding the first horizontal section.

4. The interface module as claimed in claim 3, wherein the first index robot is configured to transfer a substrate with respect to a first container placed on a first load port located at one side of the load port module, and
wherein the second index robot is configured to transfer a substrate with respect to a second container placed on a second load port of the load port module.

5. The interface module as claimed in claim 4, wherein the first index robot and the second index robot are configured to access the buffer module at different times in sequence.

6. The interface module as claimed in claim 1, wherein the index robot set is configured to transfer a substrate unloaded from the container to the lower buffer and to load a substrate received in the upper buffer into the container.

7. The interface module as claimed in claim 1, wherein the index robot set is configured to transfer a substrate unloaded from the container to the upper buffer and to load a substrate received in the lower buffer into the container.

8. The interface module as claimed in claim 1, wherein the index robot set is configured to transfer a substrate unloaded from the container to a first sub-region of the upper buffer and to load a substrate received in a second sub-region of the upper buffer into the container, and
wherein the first sub-region and the second sub-region are regions divided in the upper buffer in the vertical direction.

9. The interface module as claimed in claim 1, wherein the index robot set is configured to transfer a substrate unloaded from the container to a first sub-region of the lower buffer and to load a substrate received in a second sub-region of the lower buffer into the container, and
wherein the first sub-region and the second sub-region are regions divided in the lower buffer in the vertical direction.

10. A method of operating an interface module configured to load and unload a substrate in a substrate processing apparatus, wherein the interface module comprises:
a load port module comprising a plurality of load ports configured to allow a container accommodating a substrate to be placed thereon; and
an index module disposed on one side of the load port module, the index module being configured to unload the substrate from the container and load the substrate into a buffer module or to load a substrate processed in the substrate processing apparatus into the container,
wherein the index module comprises:
an index chamber;
vertical gantry members located at both sides of the index chamber;
a horizontal gantry member coupled to the vertical gantry members so as to be movable in a vertical direction, the horizontal gantry member extending in a first horizontal direction perpendicular to the vertical direction; and
an index robot set comprising a plurality of index robots configured to be movable along the horizontal gantry member,
wherein the buffer module comprises an upper buffer and a lower buffer disposed in the vertical direction,
wherein the index robot set comprises:
a first index robot configured to move within a first horizontal section of the horizontal gantry member; and
a second index robot configured to move within a second horizontal section of the horizontal gantry member, excluding the first horizontal section,
wherein the first index robot transfers a substrate with respect to a first container placed on a first load port located at one side of the load port module,
wherein the second index robot transfers a substrate with respect to a second container placed on a second load port of the load port module, and
wherein the method comprises:
a substrate unloading step of picking up, by the first index robot, a first substrate from the first container and picking up, by the second index robot, a second substrate from the second container;
a substrate transfer step of transferring, by the first index robot, the first substrate to the buffer module and transferring, by the second index robot, the second substrate to the buffer module;
a substrate retrieval step of picking up, by the first index robot, the first substrate processed in the substrate processing apparatus from the buffer module and picking up, by the second index robot, the second substrate processed in the substrate processing apparatus from the buffer module; and
a substrate loading step of loading, by the first index robot, the first substrate into the first container and loading, by the second index robot, the second substrate into the second container.

11. The method as claimed in claim 10, wherein, in the substrate unloading step and the substrate loading step, the first index robot and the second index robot operate independently of each other.

12. The method as claimed in claim 10, wherein, in the substrate transfer step and the substrate retrieval step, the first index robot and the second index robot access the buffer module at different times in sequence.

13. The method as claimed in claim 10, wherein the first index robot and the second index robot transfer the first substrate and the second substrate unloaded from the first container and the second container to the lower buffer, and load the first substrate and the second substrate received in the upper buffer into the first container and the second container.

14. The method as claimed in claim 10, wherein the first index robot and the second index robot transfer the first substrate and the second substrate unloaded from the first container and the second container to the upper buffer, and load the first substrate and the second substrate received in the lower buffer into the first container and the second container.

15. The method as claimed in claim 10, wherein the first index robot and the second index robot transfer the first substrate and the second substrate unloaded from the first container and the second container to a first sub-region of the upper buffer, and load the first substrate and the second substrate received in a second sub-region of the upper buffer into the first container and the second container, and
wherein the first sub-region and the second sub-region are regions divided in the upper buffer in the vertical direction.

16. The method as claimed in claim 10, wherein the first index robot and the second index robot transfer the first substrate and the second substrate unloaded from the first container and the second container to a first sub-region of the lower buffer, and load the first substrate and the second substrate received in a second sub-region of the lower buffer into the first container and the second container, and
wherein the first sub-region and the second sub-region are regions divided in the lower buffer in the vertical direction.

17. A substrate processing apparatus comprising:
an interface module configured to load and unload a substrate;
a buffer module configured to store the substrate;
a main transfer module configured to transfer the substrate to one or more process chambers configured to perform processing on the substrate; and
a processing module having the one or more process chambers arranged therein,
wherein the interface module comprises:
a load port module comprising a plurality of load ports configured to allow a container accommodating a substrate to be placed thereon; and
an index module disposed on one side of the load port module, the index module being configured to unload the substrate from the container and load the substrate into the buffer module or to load a substrate processed in the substrate processing apparatus into the container,
wherein the index module comprises:
an index chamber;
vertical gantry members located at both sides of the index chamber;
a horizontal gantry member coupled to the vertical gantry members so as to be movable in a vertical direction, the horizontal gantry member extending in a first horizontal direction perpendicular to the vertical direction; and
an index robot set comprising a plurality of index robots configured to be movable along the horizontal gantry member,
wherein the buffer module comprises an upper buffer and a lower buffer disposed in the vertical direction,
wherein the index robot set comprises:
a first index robot configured to move within a first horizontal section of the horizontal gantry member; and
a second index robot configured to move within a second horizontal section of the horizontal gantry member, excluding the first horizontal section,
wherein the first index robot is configured to transfer a first substrate with respect to a first container placed on a first load port located at one side of the load port module,
wherein the second index robot is configured to transfer a second substrate with respect to a second container placed on a second load port of the load port module, and
wherein the first index robot and the second index robot are configured to access the buffer module at different times in sequence.

18. The substrate processing apparatus as claimed in claim 17, wherein the first index robot and the second index robot are configured to transfer the first substrate and the second substrate unloaded from the first container and the second container to the lower buffer and to load the first substrate and the second substrate received in the upper buffer into the first container and the second container.

19. The substrate processing apparatus as claimed in claim 17, wherein the first index robot and the second index robot are configured to transfer the first substrate and the second substrate unloaded from the first container and the second container to the upper buffer and to load the first substrate and the second substrate received in the lower buffer into the first container and the second container.

20. The substrate processing apparatus as claimed in claim 17, wherein the first index robot and the second index robot are configured to transfer the first substrate and the second substrate unloaded from the first container and the second container to a first sub-region of the upper buffer or the lower buffer and to load the first substrate and the second substrate received in a second sub-region of the upper buffer or the lower buffer into the first container and the second container, and
wherein the first sub-region and the second sub-region are regions divided in the upper buffer or the lower buffer in the vertical direction.
